(19) United States
(12) Patent Application Publication
(10) Pub. No.: US 2018/0172229 A1
(43) Pub. Date: Jun. 21, 2018

(54) SOLAR ARRAY IN A WIRELESS TOWER

(71) Applicant: Wind Tower Technologies, LLC, Boulder, CO (US)

(72) Inventors: James D. Lockwood, Boulder, CO (US); Matthew J. Chase, Windsor, CO (US)

(21) Appl. No.: 15/849,517

(22) Filed: Dec. 20, 2017

Related U.S. Application Data
(60) Provisional application No. 62/436,852, filed on Dec. 20, 2016.

(51) Int. Cl. F21S 9/03; H01L 31/02; F21S 8/08

(52) U.S. Cl. CPC F21S 9/037; F21W 2131/103; F21S 8/086; H01L 31/02021

(57) ABSTRACT

A solar panel may include a photovoltaic cell that includes the characteristic of being thin enough to bend without imposing strain that damages the photovoltaic cell, and the photovoltaic cell is configured to wrap around a wireless communication tower.

### BACKGROUND

In wide area wireless communication networks, relatively high power base station devices are provided to serve wireless client devices or user devices. Each base station device is capable of serving wireless user devices in a coverage area that is primarily determined by the power of the signal it can transmit. Wireless service to user devices located within large buildings becomes degraded because the user device has difficulty receiving a signal from the base station, even if the building is well within the coverage area of the base station.

To augment the coverage of the wireless network, wireless transceiver devices with relatively small coverage areas (and serving capacities) are deployed. Depending on their coverage area and serving capacities, these wireless transceiver devices are referred to as “femto” cells or “pico” cells, or more generally, small cell access point devices. For simplicity and generality, the term radio access point (RAP) device is used herein to refer to a wireless transceiver device that is configured to serve wireless user devices over relatively small coverage areas and with generally less capacity as compared to a macro base station that is configured to serve a relatively large coverage area (“macro cell”) and consequently many more client devices. The RAP devices may be deployed inside or near buildings to serve client devices where signals from a macro base station are too weak.

### SUMMARY

In one embodiment, a solar panel includes a photovoltaic cell that includes the characteristic of being thin enough to bend without imposing strain that damages the photovoltaic cell, and the photovoltaic cell is configured to wrap around a wireless communication tower.

The solar panel may direct power to a battery attached to the wireless communication tower.

The battery may be located in a position of the wireless communication tower where a power meter would otherwise generally occupy.

The solar panel may be laminated.

The solar panel may charge the batteries during sunlight time periods and wireless communication devices draw electricity from the batteries during the sunlight hours and/or during time periods where the panel is without exposure to the sunlight.

The solar panel may include a single photovoltaic cell of the panel wraps around the entire circumference of the wireless communication tower.

The solar panel may occupy at least a fifth of the length of the wireless communication tower's height.

The battery may be located at a base section of the wireless communication tower.

The panel may be located at a base section of the wireless communication tower.

The panel may be coated with a hydrophobic material that prevents at least some water based substances from adhering to the panel.

The panel may include a self-cleaning mechanism.

The wireless communication tower may include at least one reflector attached to its exterior that directs light towards the solar panel.

The reflector may be positioned above the panels and above regions of the wireless communication tower where shadows are typically cast.

The solar panel may receive light regardless of the position of the sun during daylight periods.

The battery may be in communication with at least one wireless communication device incorporated into the wireless communication tower.

The solar panel may include a processor that causes the wireless communication device to send a message relating to power generation involving the solar panel.

The message may include an amount of power generated with the solar panel.

The message may include an amount of power stored in the battery.

The message may include an amount of power used by the wireless communication tower.

In one embodiment, a solar panel includes a photovoltaic cell configured to wrap around a wireless communication tower.

In one embodiment, a wireless communication tower includes a solar panel attached to its outside surface.

The wireless communication tower may include the solar panel wrapped around a diameter of the wireless communication tower.

In one embodiment, a wireless tower includes a photovoltaic material wrapped around an exterior of the wireless tower.

Any of the aspects of the principles detailed above may be combined with any of the other aspect detailed herein.

### BRIEF DESCRIPTION OF THE DRAWINGS

The accompanying drawings illustrate various embodiments of the present apparatus and are a part of the specification. The illustrated embodiments are merely examples of the present apparatus and do not limit the scope thereof.

FIG. 1 depicts an example of a pole in accordance with the present disclosure.

FIG. 2 depicts an example of a pole in accordance with the present disclosure.

FIG. 3 depicts an example of equipment disposed within a pole in accordance with the present disclosure.

FIG. 4 depicts an example of a housing in accordance with the present disclosure.

FIG. 5 depicts an example of a pole in accordance with the present disclosure.

FIG. 6 depicts an example of lower base structure in accordance with the present disclosure.

FIG. 7 depicts an example of a connection in accordance with the present disclosure.

FIG. 8 depicts an example of a pole in accordance with aspects of the present disclosure.

FIG. 9 depicts an example of a connection in accordance with aspects of the present disclosure.

FIG. 10 depicts an example of a connection in accordance with aspects of the present disclosure.

FIG. 11 depicts an example of a solar panel in accordance with aspects of the present disclosure.

FIG. 12 depicts an example of a wireless tower in accordance with aspects of the present disclosure.

FIG. 13 depicts an example of a wireless tower in accordance with aspects of the present disclosure.

The attached drawings show various views and optional dimensions, according to various exemplary embodiments, for the various components of the small cell smart pole. Throughout the drawings, identical reference numbers designate similar, but not necessarily identical, elements.

### DETAILED DESCRIPTION

Particularly, with reference to the figures, the exemplary system includes a small cell smart pole that is intended to be located in an urban area while assimilating with its urban surroundings. In the present embodiment, the system simulates the look and feel of a street light pole to prevent distraction from the natural urban setting. According to the exemplary embodiment, the tower includes two different diameters. The larger diameter is configured to support the upper small cell antenna and the smaller diameter is configured to mount the internal small cell equipment. Various sizes may be used to allow for correct housing of desired equipment.

According to the exemplary embodiment, the smaller diameter interior steel spine is configured to mount the equipment efficiently and to reduce the outer diameter of the shroud. In alternative examples, the equipment is hung from rods and supported in an internal platform. In some of these alternative examples, no smaller diameter interior steel spine is needed to mount the equipment. According to one exemplary embodiment, the equipment structure (encased by a cylindrical shroud) and antenna structure (larger tube mounted above the cylindrical shroud structure below) is separated by a flange connection to allow for an independent installation of upper tower and lower equipment.

The exemplary clam shell design allows for complete removal of the shroud and full access of all equipment, facilitating installation and change out or service. Furthermore, a Port Hole is included for viewing the meter from the outside, adding convenience.

An exterior access to switch shut off enables function of the pole without additional tools or instruments. Further, cable ducts in the upper steel pipe streamline cabling.

According to one exemplary embodiment, the system includes an optional steel vault for security.

The lower shroud of the present design can be made out of precast concrete, steel, aluminum, cast iron, another metal, composites, and the like. As illustrated in the exemplary drawings, the precast lower shroud includes passages to the inner cavity to allow for the installation and maintenance of the internal small cell equipment. As detailed in the exemplary figures, the passages or port holes formed in the precast concrete lower shroud may be large for access to the interior of the shroud. Additionally, the arched shape of the openings operates to structurally transfer any loads imparted on the shroud to the foundation.

Additionally, a number of fasteners, such as threaded posts or bolts, are formed on the upper surface of the precast lower shroud to facilitate attachment of the upper shroud and the upper small cell antenna. Access panels and doors may be mounted to the precast lower shroud to enclose the small cell equipment from the elements, while providing selective access, when desired, to modify, regulate, change out, or otherwise access the small cell equipment. According to one embodiment illustrated in the figures, a housing including a half door may be constructed to fit around the precast concrete structure to enclose the internal equipment. The housing may include locks, hinges, access doors, vents for passive radiant cooling, and/or viewing ports. Cable ports and other features may be formed in the precast base during manufacture.

According to the present exemplary embodiment, the pre-casting of the lower shroud allows for easy match of existing architecture. Specifically, casting molds can be made to simulate existing light pole architecture. In fact, the molds for the precast lower shroud may be molded directly from an existing light pole.

Additionally, the present exemplary system includes a distinct two-part design: the lower shroud and the upper shroud. Incorporating a two-part construction allows for easier construction and implementation during set-up. According to the present exemplary embodiment, the precast concrete shell used for the lower shroud can be installed separately from the upper antenna structure. Additionally, the equipment contained in the lower shroud may be installed at a later time than the installation of the lower shroud, adding flexibility during installation.

The steel door shell described above provides added flexibility to the construction in that it allows for complete removal of shroud and full access through the precast port holes of all equipment; both during installation and during change out or service. The modularity of the present system allows for replacement of individual components in the case of failure or construction change, without the undue expense of replacing the entire system.

Further features that may be incorporated into the present exemplary construction including a precast lower shroud include a port hole formed in the steel door shell for viewing the meter in the equipment from the outside. A passage may also be formed in the steel door shell for exterior access to switch shut off. The access passage may be gasketed to maintain a hermetic seal to the interior of the precast lower shroud. Additional features and ports may be formed in the steel door shell without impacting the structural integrity of the system, which structural integrity is provided by the precast lower shroud.

As illustrated in the Figures, a number of cable ducts may be formed in the center precast lower shroud. This allows passage of the cables from the lower shroud into the center of the upper tower section, to the antenna. The upper shroud is configured to cover the cables into the antenna.

In some cases, the pole is intended to be located in an urban area while assimilating with its urban surroundings. The system may simulate the look and feel of a street light pole to prevent distraction from the natural urban setting. According to one example, the tower includes two different diameters. The larger diameter is configured to support the upper small cell antenna and the smaller diameter is configured to mount the internal small cell equipment. Various sizes may be used to allow for correct housing of desired equipment.

In one example, a smaller diameter interior steel spine is to mount the equipment efficiently and to reduce the outer diameter of the shroud. In some cases, an equipment structure (encased by a cylindrical shroud) and antenna structure (larger tube mounted above the cylindrical shroud structure below) is separated by a flange connection to allow for an independent installation of upper tower and lower equipment.

The clam shell may allow for complete removal of the shroud and full access of all equipment, facilitating installation and change out or service. Furthermore, a port hole may be included for viewing the meter from the outside. An exterior access to switch shut off may enable function of the pole without additional tools or instruments. Further, cable ducts in upper steel pipe may streamline cabling. According to one example, the system includes an optional steel vault for security. The upper shroud may be configured to cover cables into the antenna. Further, the slim tower construction option may be compatible with a new Compact Metro Radio Outdoor (CMRO's) cells that improve LTE capacity and performance in high-density areas. Also, passive ventilation may be provided in the current system for power cabinet and the remote radio head (RRH).

According to the exemplary embodiment, the interior of the larger diameter structure is open to facilitate access to and receipt of electronic components. According to the illustrated embodiment, the metal base system may be empty except for the inclusion of one or more structural cross supports. In one embodiment, the cross supports are attached to the internal cavity of the metal base system by magnets, specifically, in one exemplary embodiment, rare earth magnets. The use of magnets allows for hassle free and efficient customization of the metal base system by an installer, while allowing for added structural or transverse support for the structure itself.

In alternative examples, the equipment is hung from rods and supported in an internal platform. In some of these alternative examples, no smaller diameter interior steel spine is needed to mount the equipment. According to one exemplary embodiment, the equipment base structure and antenna structure (longer tube mounted above the cylindrical base structure) is separated by a flange connection to allow for an independent installation of upper tower and lower equipment. While the exemplary structure is illustrated as having a circular cross-section, any number of geometries may be incorporated into the present exemplary structure. Particularly, any number of cross-sections may be adopted to match the architectural construction of the surrounding features.

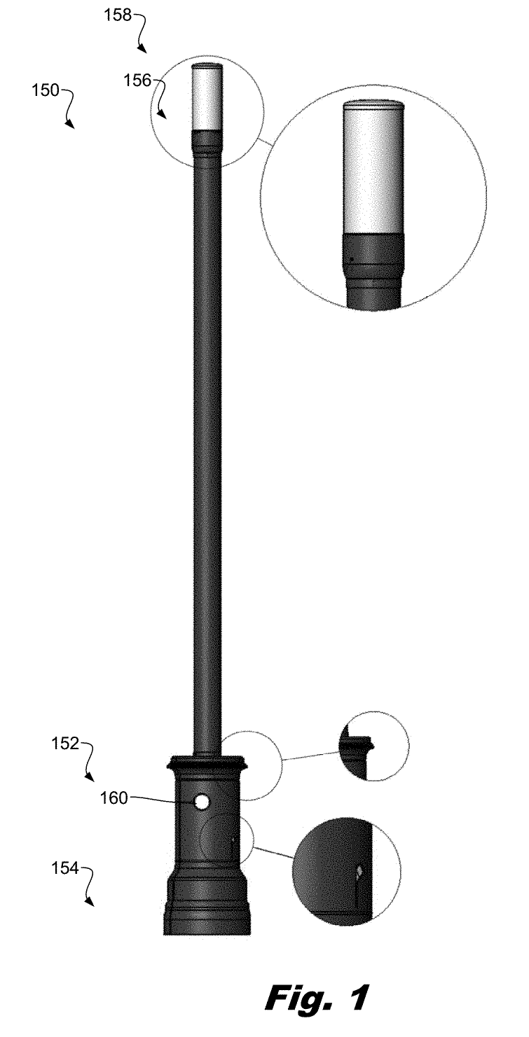

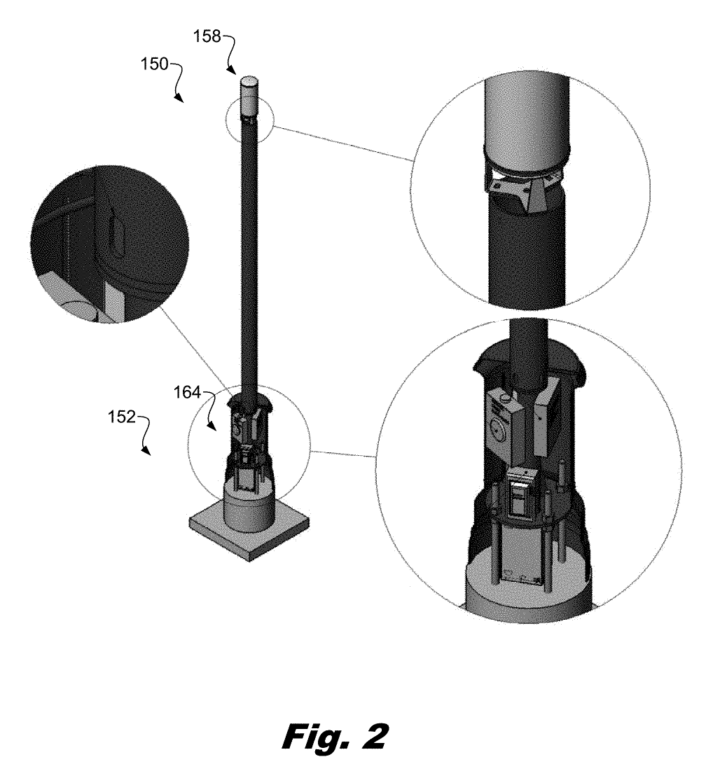

FIGS. 1 and 2 depict an example a pole 150. The lower base structure 152 of the pole 150 is made out of a metal enclosure having a lower flange 154 connected thereto for mounting to the ground or a subgrade enclosure, and an upper receiving flange 156 for receiving and coupling the antenna structure 158 and small cell equipment to the larger equipment cabinet, or lower base structure. As illustrated in the exemplary drawings, the metal lower base structure 152 includes passages 160 to the inner cavity 162 to allow for the installation and maintenance of the internal small cell equipment 164. Additionally, a number of fastener receiving orifices are formed on a flange of the upper surface of the lower base structure to facilitate attachment of the upper shroud and the upper small cell antenna.

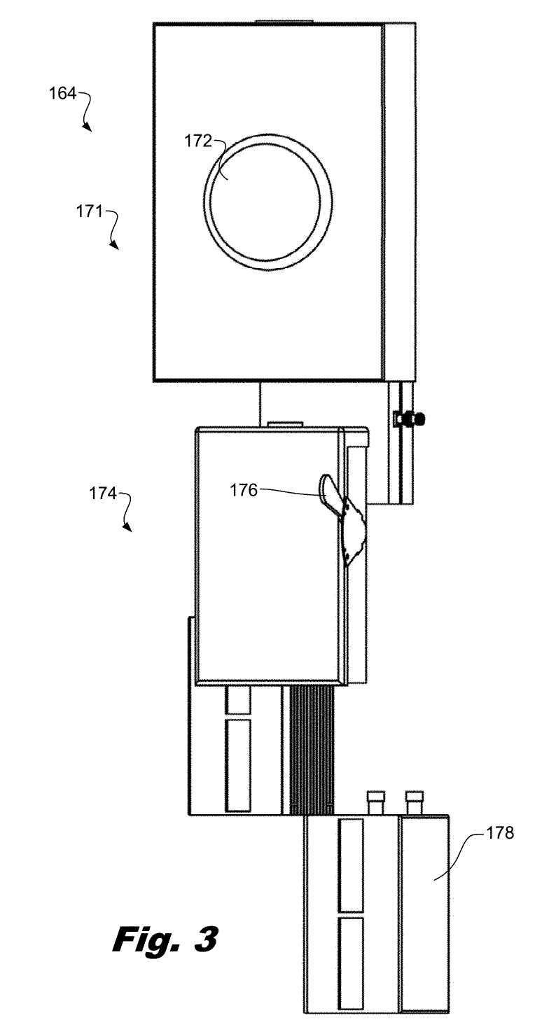

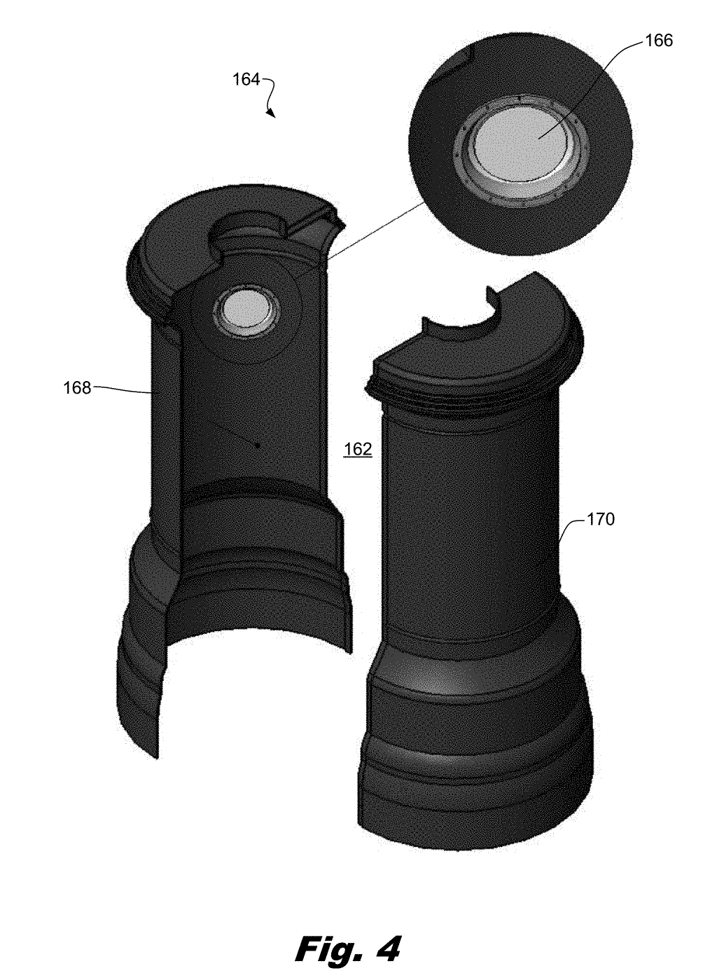

FIGS. 3 and 4 depict an example of equipment 164 that may be disposed within the inner cavity 162. In this example, the equipment is depicted as having an electronic panel 171, meter 172, a diplexer 174, a safety switch 176, and a cMRO 178. The cavity may include any appropriate type of equipment including, but not limited to, sensors, switches, batteries, processors, memory, dash boards, displays, other types of equipment, or combinations thereof.

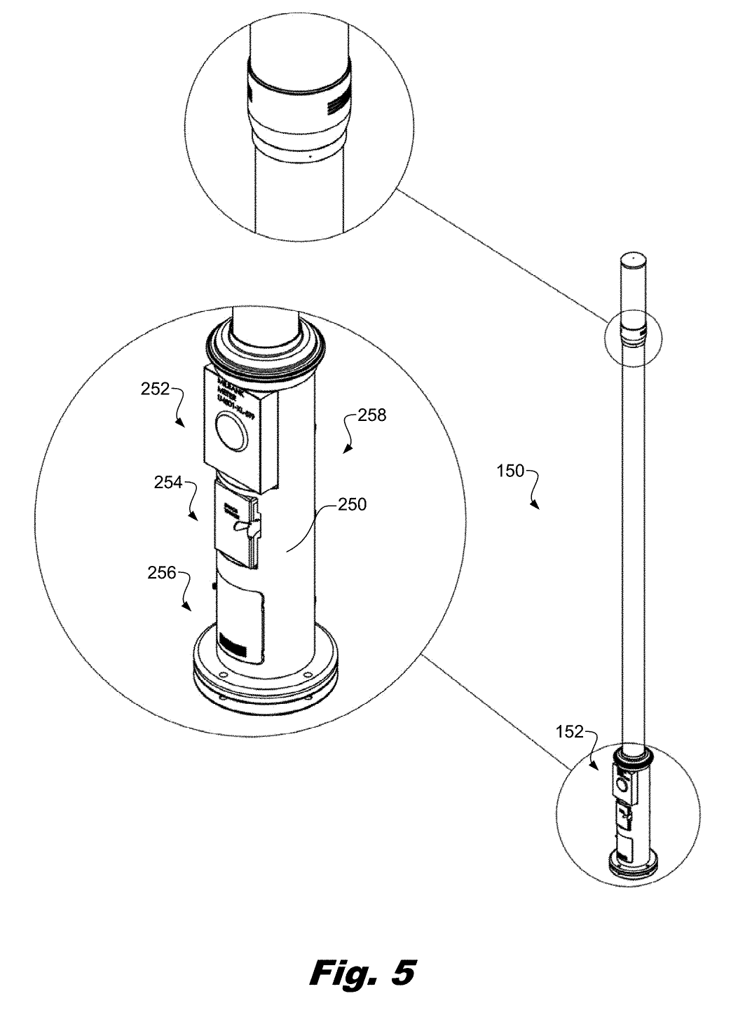

FIG. 5 depicts an example of a door shell 165 that may be used to cover the equipment disposed within the cavity 162 of the lower base structure. In this example, the door shell includes a first part 168 and a second part 170 that may be connected to one another to form a continuous barrier around the equipment. In some examples, a port hole 166 is defined in at least one of the parts of the door shell 165. Access panels and doors may be mounted to the metal lower base structure to enclose the small cell equipment from the elements, while providing selective access, when desired, to modify, regulate, change out, or otherwise access the small cell equipment. According to one embodiment illustrated in the figures, a half door may be constructed to attached to the lower base structure to enclose the internal equipment. The housing may include locks, hinges, access doors, vents for passive radiant cooling, and/or viewing ports. Cable ports and other features may be formed in the metal base during manufacture.

According to one embodiment, the lower metal base is made out of steel. Alternatively, any number of structural materials may be used for the lower base including, but in no way limited to, precast cement, aluminum, composites, structural polymers, combinations of the same, and the like. As illustrated in the figures, the upper shroud may be configured to cover the cables extending from the internal small cell equipment, up the upper shroud, into the antenna.

In one embodiment, the pole system includes a composite shroud that fits over the junction formed by the attachment of the upper small cell antenna to the lower metal base. The composite shroud provides for the ability to customize the structure to aesthetically fit in with the architectural theme of the location where the pole system is being installed. Additionally, the modular system allows for separate crews to do the installation allowing one crew to install the metal base system, and a second crew to install the components and/or upper antenna structure.

The modular aspect of the exemplary pole system allows for customization of the system and the resulting pole such that it will fit in with the desired environment. In one exemplary embodiment, the lower flange of the metal base may be connected to a subgrade cabinet or hollow foundation system that includes a mating top flange. According to this embodiment, the subgrade hollow foundation system includes additional space for components, may include a lifting mechanism for lifting electrical components to ground level for access, and may be made of any number of materials, including, but in no way limited to, a precast cement structure.

According to one illustrated embodiment, a port hole is included for viewing the meter, contained within the lower cabinet, from the outside, adding convenience for monitoring and maintenance. An exterior access to switch shut off enables function of the pole without additional tools or instruments. Further, cable ducts in the upper steel pipe streamline cabling. According to one exemplary embodiment, the system includes an optional steel door hingedly connected to the base structure. The steel door provides access to the internal components of the metal base structure.

The lower base structure may be made of any appropriate material. A non-exhaustive list of materials includes metal, aluminum, steel, stainless steel, composites, other types of materials, or combinations thereof. As illustrated in the exemplary drawings, the lower base structure includes passages to the inner cavity to allow for the installation and maintenance of the internal small cell equipment. As detailed in the exemplary figures, the passages or port holes formed in the lower metal base structure may be large for access to the interior of the base structure. Additionally, the openings may include an arched shape to structurally transfer any loads imparted on the base structure to the foundation.

Additionally, a number of fasteners, such as threaded posts, bolts, threaded orifices, or pass-through orifices may be formed on the upper surface or flange of the lower base structure to facilitate attachment of the upper shroud and the upper small cell antenna. Access panels and doors may be mounted to the lower base structure to enclose the small cell equipment from the elements, while providing selective access, when desired, to modify, regulate, change out, or otherwise access the small cell equipment. According to one embodiment illustrated in the figures, a housing including a half door may be hingedly coupled to the lower base structure to enclose the internal equipment. The lower base structure or any attached doors or panels may include locks, hinges, access doors, vents for passive radiant cooling, and/or viewing ports. Cable ports and other features may be formed in the base during manufacture.

According to the present exemplary embodiment, the lower base structure may be cast, machined, welded, formed in a single piece, formed via the connection of multiple components, and the like to allow for easy match of existing architecture. Specifically, casting molds can be made to simulate existing light pole architecture. In fact, the molds for the lower base structure may be molded directly from an existing light pole.

Additionally, the present exemplary system includes a distinct two-part design: the lower base structure and the upper shroud. Incorporating a two-part construction allows for easier construction and implementation during set-up. According to the present exemplary embodiment, the lower base structure can be installed separately from the upper antenna structure under a single installation permit from the local permitting authorities. Additionally, the equipment contained in the lower base structure may be installed at a later time than the installation of the lower base structure, adding flexibility during installation.

The steel door described above provides added flexibility to the design in that it allows for full access through the port holes of all equipment; both during installation and during change out or service. The modularity of the present system allows for replacement of individual components in the case of failure or design change, without the undue expense of replacing the entire system.

The metal lower base structure may include a port hole formed in the steel door for viewing the meter in the equipment from the outside. A passage may also be formed in the steel door for exterior access to switch shut off. The access passage may be gasketed to maintain a hermetic seal to the interior of the lower base structure. Additional features and ports may be formed in the steel door shell without impacting the structural integrity of the system, which structural integrity is provided by the lower base structure.

As illustrated in the Figures, a number of cable ducts may be formed in the center lower base structure. This allows passage of the cables from the lower base structure into the center of the upper tower section, to the antenna. The upper shroud is configured to cover the cables into the antenna. Further, the slim tower design option is compatible with new Compact Metro Radio Outdoor (CMRO's) cells that improve LTE capacity and performance in height-density areas. Furthermore, passive ventilation is provided in the current system for power cabinet and the remote radio head (RRH). While this example has been described with reference to a specific types of door shell arrangement, any appropriate type of housing may be used to protect the equipment.

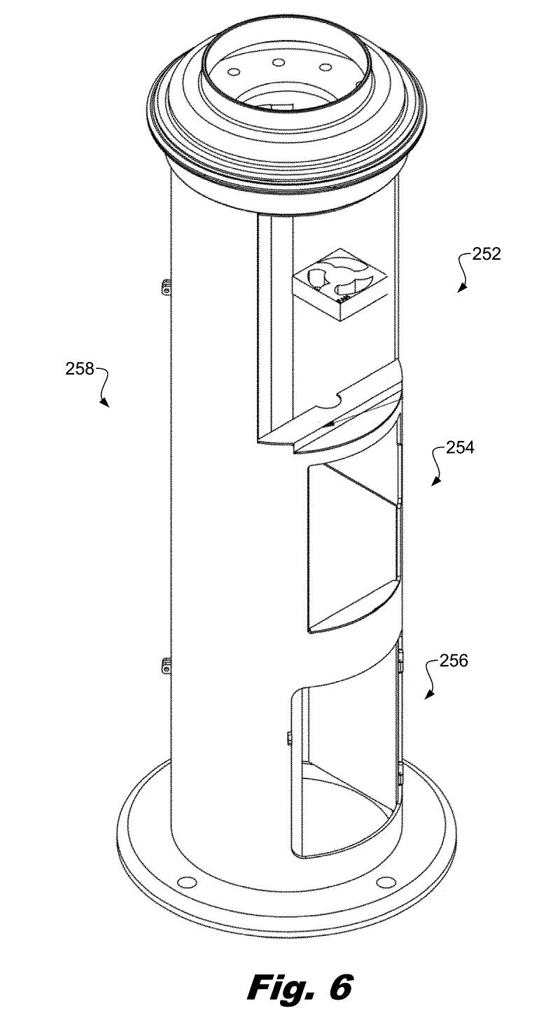

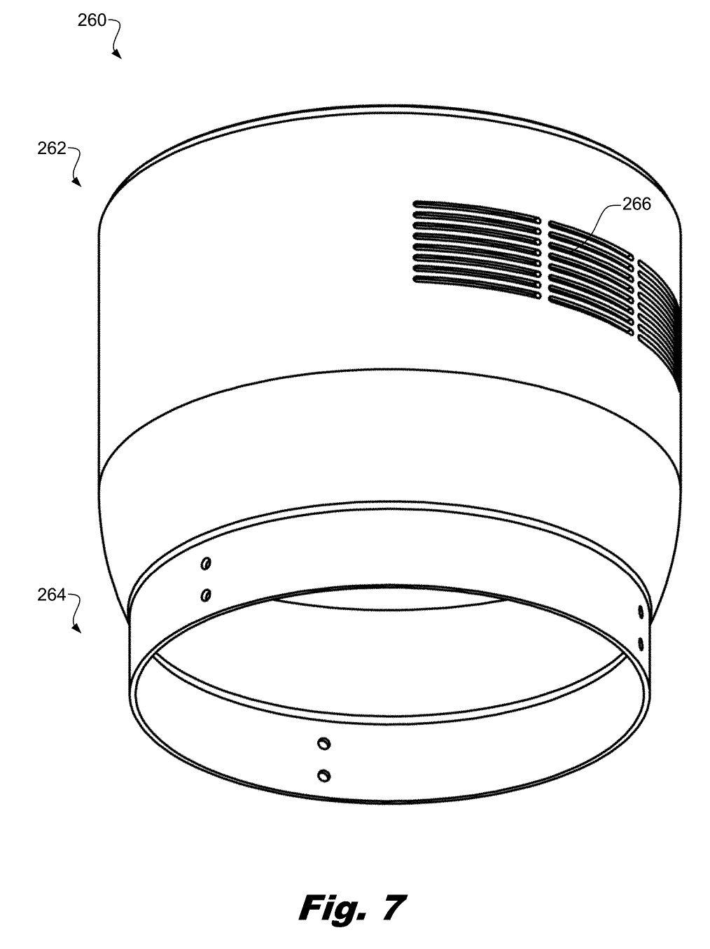

FIGS. 6 and 7 depict an alternative example of a pole 150. In this example, the pole 150 with a lower base structure 152. In this example, the lower base structure may include a steel enclosure 250 with multiple mounting brackets. The first mounting bracket 252 may be used secure the meter to the pole, and a second mounting bracket 254 may be used to secure the cMRO to the pole. The lower base structure 152 may also include an internal cavity that may include any appropriate type of equipment.

In some cases, the equipment mounted in the brackets is physically separated from the equipment disposed within the internal cavity defined by the inside of the steel enclosure. In some cases, wireless equipment is secured to the pole in the external brackets and the power equipment is stored on the inside of the pole in the cavity. In other examples, the backside of the brackets include openings so that wires, cables, or other components may physically connect the equipment in the brackets with the equipment in the cavity. Access to the internal cavity may be obtained through at least one door incorporated into the lower base structure. In one example, a first door 256 is located beneath the brackets, and a second door 258 is incorporated into the lower base structure on an opposite side to the brackets.

Another type of pole, such as light pole (also known as street light) may include a light source spaced above the ground by a shaft. Often the light poles are located on the edge of a road or walkway and provide light to the surrounding area. In some cases, the light poles are connected to each other underground, but in other cases the light poles are wired from one utility post to another. Often, street lighting uses high-intensity discharge lamps. These lamps provide the relatively large amount of illumination compared to the rate of electricity consumption. Some street lighting includes light emitting diodes (LED) or induction lights, which emit a white light that provides high levels of scotopic lumens for low wattages. Further, photovoltaic-powered LED luminaires are sometimes used.

A utility pole (also known as a transmission pole) may include a column or post used to support overhead power lines and various other public utilities, such as cable, fiber optic cable, and related equipment such as transformers, lights, and wireless communication transmitters. Electrical wires and/or cables may be routed overhead on utility poles. Hanging these wires and/or cables overhead insulates the wires from the ground and keep the wires out of the way of people and vehicles. Utility poles are often made of wood, metal, concrete, or composites like fiberglass.

Sub-transmission lines may be suspended on utility poles that carry higher voltage power between substations. Sub-transmission lines include three wires and occasionally include an overhead ground wire. This overhead ground wire operates like a lightning rod, providing a low resistance path to ground to protect the phase conductors from lightning.

Distribution lines may distribute lower voltage power to households and other buildings. Distribution lines may be a grounded-wye system or a delta system. A delta system may involve a single conductor for each of the three phases. A grounded-wye system may involve a fourth neutral conductor that is grounded. Some poles include a pole-mounted step-down transformer that modifies the characteristics of the electricity for distribution to residential and light commercial loads. The pole may be grounded with a bare copper or copper-clad steel wire running down the pole, attached to the metal pin supporting each insulator, and connect at the bottom to a metal rod driven into the ground. In some cases, every pole in a distribution system is grounded. In other systems, only some of the poles are grounded.

Many utility poles are made of wood and are pressure-treated with some type of preservative for protection against rot, fungi and insects. Other common utility pole materials are steel and concrete, and composites (e.g. fiberglass). A vertical space on the pole that is reserved for equipment is sometimes called the supply space. The supply space is often located at the top of the pole above the communication cables for safety reasons. The wires are usually uninsulated and are connected to the poles through insulators. The insulators are often mounted on a horizontal cross-arm. In some cases, communications cables are attached to the pole below the electric power lines. This vertical space along the pole is sometimes referred to as the communications space. Common types of communication cables are copper cables, fiber optic cables, and coaxial cables.

Conventional poles are often made of wood, but some poles are made of non-wood materials. These non-wood materials often include concrete, steel, and fiber-reinforced composite. Concrete poles are used in marine environments and coastal zones where corrosion resistance is desired. Also, the heavy weight of the concrete helps the poles resist high winds. A conventional concrete pole may be tapered made of solid concrete. Other conventional concrete poles include pre-stressed concrete or a hybrid of concrete and steel. Drilling holes into the concrete poles is often considered to be unfeasible, and thus, it is desired to cast hardware in place during the curing stages of manufacturing the poles.

Steel poles may provide advantages for high-voltage lines because steel poles may be manufactured to be taller, thus providing enhanced clearances from the ground, people, and vehicles. Tubular steel poles are typically made from galvanized steel. Although steel poles can be drilled on-site with certain types of drill bits, drilling holes into the steel towers is not a preferred practice, especially where the bolt holes could be built into the steel pole during manufacturing. Thus, options for connecting new hardware to steel towers includes welding attachment hardware to steel poles. However, the practical hazards of welding in the field may make this process undesirable or uneconomical.

Fiber-reinforced composite poles include those poles that combine fiberglass with cross-linked resins that produce a lightweight, weather-resistant structure. Generally, fiber-reinforced composite poles are hollow similar to the tubular steel poles, with a typical wall thickness of ¼ to ½ inch with an outer polyurethane coating that is ˜0.002-inch thin. Fiber-reinforced composite poles are not easily mounted with the traditional climbing hardware of hooks and gaffs. Fiber-reinforced composite poles can be either pre-drilled by the manufacturer or the holes can be drilled on site.

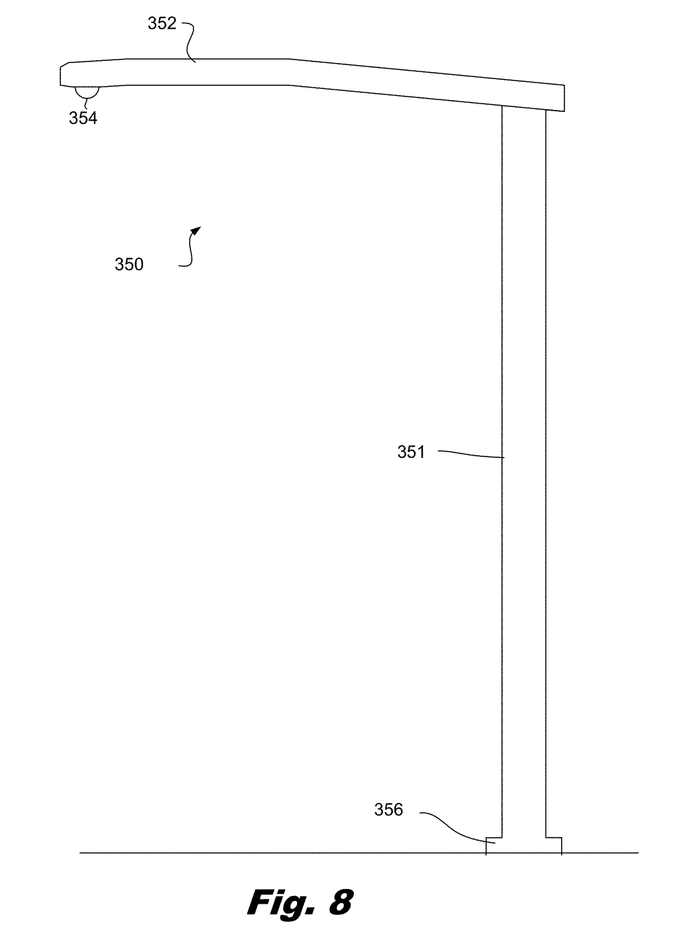

FIG. 8 depicts an example of a light pole 350 with a shaft 351 that connects to an arm 352. The arm supports a light 354 on the arm's distal end. The shaft is connected to a base on a lower end of the shaft. In the illustrated example, the flange 356 of the shaft is depicted at the bottom of the shaft. While FIG. 15 depicts the pole as a light pole, any appropriate type of pole may be used. For example, the pole may be a utility pole, a sub-transmission pole, a distribution pole, a wireless communication pole, a monopole, another type of pole, or combinations thereof.

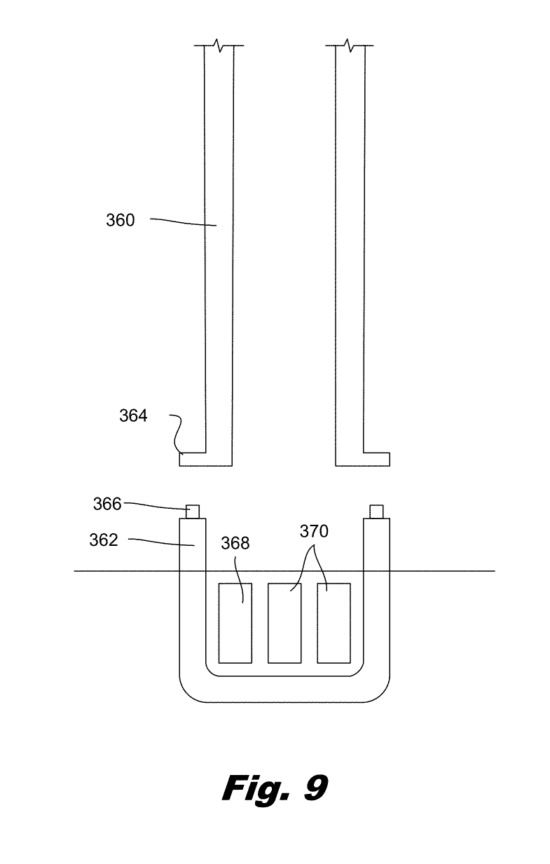

FIG. 9 depicts an exploded cross-sectional view of an example of a pole. In this example, the pole has a shaft 360 that connects to a base 362. The shaft includes a flange 364 with multiple openings for receiving threaded bolts 366. With the bottom of the shaft situated on the base and threaded bolts aligned and interconnected with the flange's bolt holes, bolt nuts can be used to secure the flange (and therefore, the shaft) to the base.

The base may be at least partially underground. By keeping at least a portion of the base underground, the pole's entire center of gravity may be kept low to the ground, or even underground, thereby increasing the pole's stability.

The base may also be hollow and provide a space for batteries 368, electronics 370, processors, memory, sensors, timers, thermometers, other types of devices, or combinations thereof. These devices may be used to provide power to the light, determine when to turn the light on and off, how bright to illuminate the light, and run other features of the pole. In those embodiments where the pole is a utility pole carrying wires or cables, the devices may determine when there is a safety issue and cause power to be cut to the line or take other types of remedial actions in the event of a dangerous situation.

These devices may be in communication with sensors that are attached to the pole. A non-exhaustive list of sensors that may be attached to the pole include, but are not limited to, a weather sensor, a thermometer, a daylight sensor, a wind sensor, a pollution sensor, an opacity sensor, a clock, another type of sensor, or combinations thereof.

Other devices that may be stored in the cavity defined by the base include control devices. The control devices may reduce energy consumption of a light pole by controlling a circuit of street lights and/or individual light poles. In some cases, the control devices may control more than more poles or more equipment than just the pole. The devices may send and receive instructions through data networks from devices located within or outside of the pole.

In some cases, the device may be part of an intelligent street lighting system that adjusts light output based on need. For example, the light pole may illuminate the area based on the presence of people, time of day, classification of pedestrian, cyclists, or automobiles, other factors, or combinations thereof. In some conditions, the intelligent street lighting system factors in road conditions, weather, presence of dangerous conditions (e.g. deer crossing, etc.). Some poles may have light-sensitive photocells that activate automatically based on the amount of ambient light.

One benefit to this type of pole is a consistent and reliable installation procedure for many different types of poles. In other words, the base may be interchangeable with many different pole types and/or pole brands. The contractors may hire a crew to install the base before knowing which aesthetic look is desired for the pole. In some cases, the pole may be customized to match the local community or the other poles in the area.

The base may be made of any appropriate type of material. For example, the base may be made of a pre-cast material, steel, a composite material, and so forth.

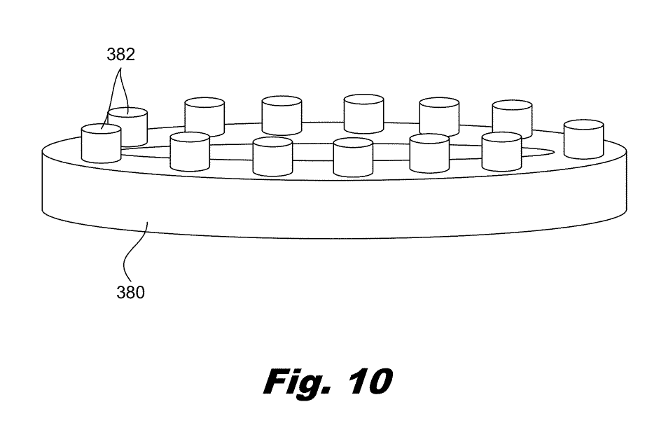

FIG. 10 depicts an example of a top portion of the base 380. In this example, the base includes a ring of threaded bolts 382 that can be used to attach the shaft's flange to the base. While this example is depicted with bolts for attaching the shaft to the base, any appropriate type of mechanism may be used to attach the base to the shaft. For example, alternative connection mechanisms may include other types of fasteners, compression fits, adhesives, another type of connection mechanism, or combinations thereof.

While the examples above have depicted the base with specific shapes and dimensions, any appropriate type of base may be used in accordance with the principles described herein. For example, the base may include a narrow section that is configured to attach to the shaft. In other examples, the base may include a relatively wide section that is used to connect to the shaft. Further, just a portion of the base may be configured to be located in a subterranean space, while in other examples, the all of the bases may be configured to be buried under the ground level.

Solar panels may include multiple photovoltaic cells that are combined to form a panel. Solar panels may generate electricity by converting sunlight into an electrical current. The current generated by a solar panel is direct current (DC). However, this electricity can be converted into alternating current (AC) to work properly in environments that use alternative current. Generally speaking, conventional solar panels include rigid panels that are relatively inflexible and are mounted onto flat surfaces.

The principles described herein include bendable solar panels that can be placed on any surface, including wireless communication towers. Bendable, flexible solar panels are facilitated by making the solar panels thinner without causing damage or stress on the solar cells. In some cases, the solar cells may be wrapped around the diameter (or at least part of the diameter) of a wireless tower.

The solar cells may be any appropriate thickness. In some examples, the thickness includes only one micrometer thick, multiple micrometers thick, thinner than a human hair, thin as paper, thin as multiple papers, or another appropriate thickness. In some cases, the solar cell is made from the semiconductor gallium arsenide or another appropriate material.

One advantage to having the solar panel wrapped around the wireless tower is that as the sun rises and sets, the tower may continuously receive light from the sun due to the tower's cylindrical surface. During the day, the tower may run electronic devices as well as charge the battery banks. Batteries may be included in the tower. The batteries may include a 12 volt battery bank linked in series for storing power during peak sun hours.

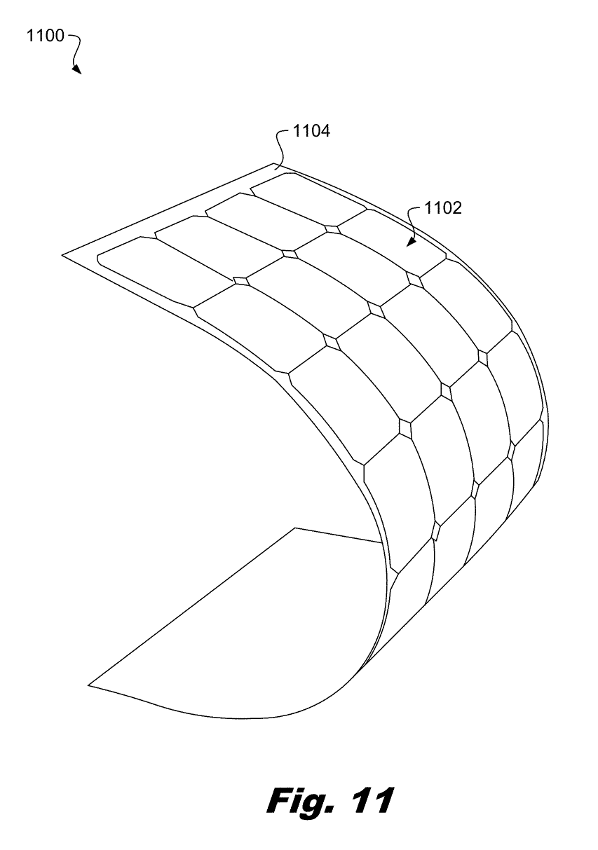

Referring now to specific examples, FIG. 11 depicts an example of a solar panel 1100. In this example, the solar panel includes multiple solar cells 1102 disposed on a first surface 1104 of the solar panel 1100. The solar panel 1100 is depicted in a flexed orientation representing the ability of the solar panel 1100 to bend without imposing a force that disables the solar cells 1102.

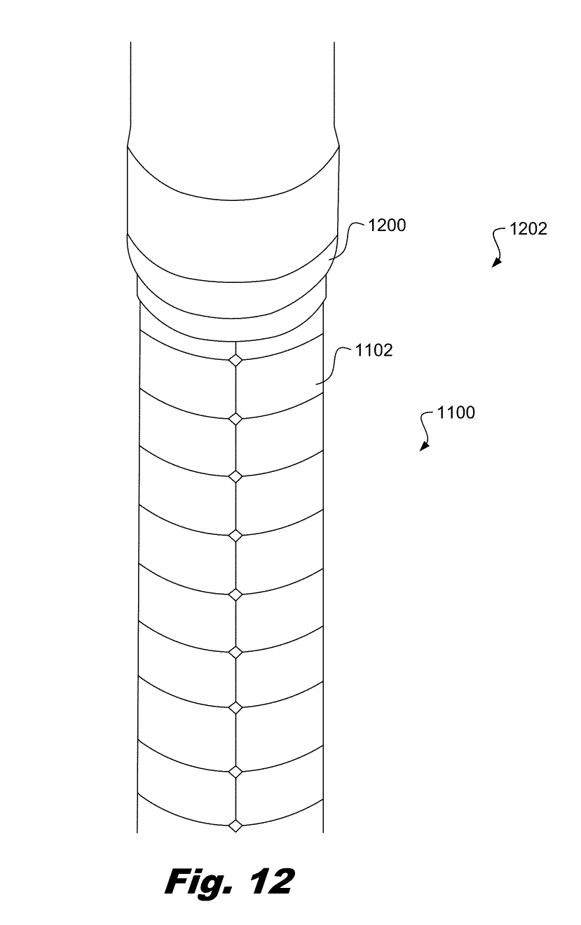

FIG. 12 depicts an example of a solar panel 1100 wrapped around an exterior surface 1200 of a wireless tower 1202. In this example, the solar panel 1100 may be attached to the exterior surface 1200 through any appropriate mechanism including fasteners, screws, nails, tape, adhesives, magnets, other types of fasteners, or combinations thereof. The solar panel may be flexible enough to wrap around the exterior surface 1200 of the wireless tower 1202 so that the solar panel 1100 can conform to the shape of the wireless tower's shape. In some cases, the shape of the exterior surface 1200 is circular. While described as circular, the tower 1202 may assume any appropriate shape, such as an ovular shape, a rectangular shape, a square shape, a symmetric shape, an asymmetric shape, a triangular shape, another type of shape, or combinations thereof.

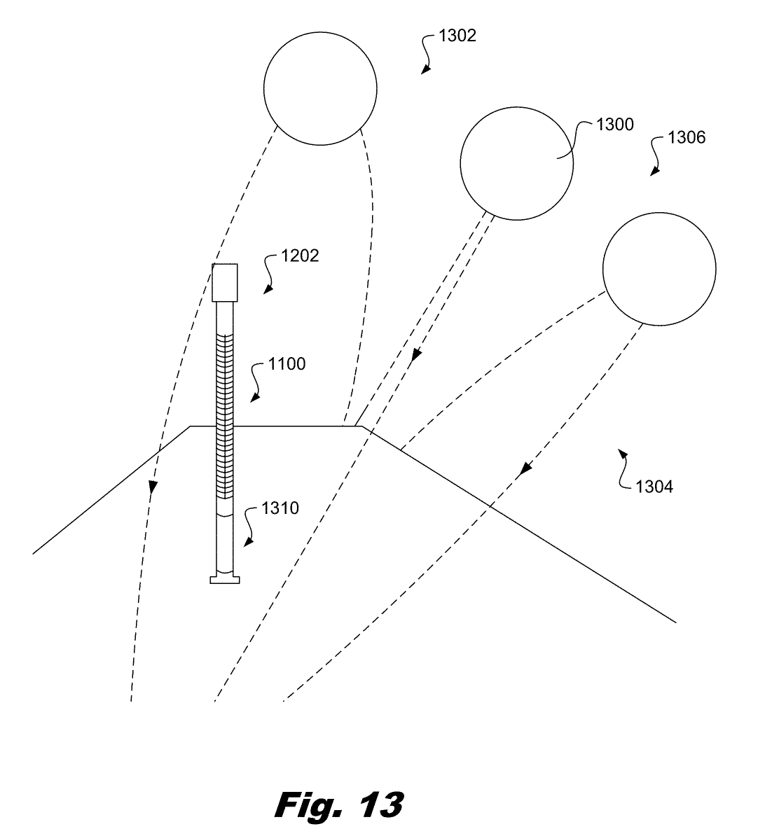

FIG. 13 depicts an example of the sun 1300 radiating solar energy on the wireless tower 1202 and the solar panels 1100 attached to the exterior of the wireless tower 1202. The sun 1300 is depicted on different trajectories. The first trajectory 1302 represents the trajectory of the sun during the summer solstice, the second trajectory 1304 represents the trajectory of the sun during the winter solstice, and the third trajectory 1306 represents a trajectory of the sun during the spring or autumn time. An advantage of wrapping the solar panel 1100 around the outside of the wireless tower is that, regardless of the time of day or the season of the year, as depicted in the example of FIG. 13, a portion of the solar panel can receive solar energy from the sun 1300.

The illustrated examples also depicts batteries 1310 connected to the wireless tower 1202. As solar energy is converted by the solar cells into electrical power, the electrical power may be transmitted to the batteries 1310, for storage. In some examples, the batteries include enough storage to power a light connected to the wireless tower during the night. In some cases, the batteries include enough storage to provide enough power to operate any appropriate operation of the wireless tower 1202 for an 24-hour period.

One of the advantages to having the solar panel wrapped around the outside of the tower is that there is generally a portion of the tower that casts a shadow over another side of the tower at any given moment. With the solar panel on all sides of the wireless tower, a section of the solar panel may always be in contact with the sun when the sun is emitting solar energy to the land on which the tower stands. Conventional outdoor equipment may use a solar panel, but the traditional solar panel is configured to face one direction at a time. Generally, conventional solar panels are static and configured to face the sun in a single direction. More complicated structures may include a solar panel with a motor that allows the solar panel to rotate to follow the sun as the sun moves along its trajectory. An advantage to the principles described herein is that no moving parts are used to receive continuous direct sunlight while the sun is shining in the area.

Another advantage of the principles described herein is that the solar panels may convert enough solar energy that the wireless tower may be positioned at a remote location without having to build infrastructure to power the wireless tower. In some examples, the wireless tower may be connected to the grid. In those examples, the wireless tower may offset at least a portion of its power requirements with the solar panels, and if there is excess power, that excess may be contributed to the grid. In some cases, the solar panels and batteries are configured to power the other types of equipment that are located near the wireless tower.

In one embodiment, a solar panel includes a photovoltaic cell that includes the characteristic of being thin enough to bend without imposing strain that damages the photovoltaic cell, and the photovoltaic cell is configured to wrap around a wireless communication tower.

To get the photovoltaic materials to be thin enough, the materials may deposited on substrates in a vacuum chamber. In some cases, multiple layers of materials are deposited to achieve the efficiencies and desired thickness. In some cases, the deposits may be made by coating conductive polymer electrodes with oxidative chemical vapor through chemical vapor deposition. In some cases, the photovoltaic cells may be printed with a 3D printer, an inkjet printer, another type of printer, or combinations thereof.

The photovoltaic materials may be deposited on any appropriate type of substrate such as glass, fiberglass, metals, polymers, other types of substrates, or combinations thereof. In some cases, the substrates are thin as well to provide flexible support to the solar cells. In some cases, the substrate may be paper. In other examples, the substrate is a material other than paper, but is approximately the thickness of the paper.

The solar panels may be finished with a UV-resistant fluoropolymer, thermoplastic olefin, glass, another type of material, or combinations thereof. The solar cells may be sealed so water and oxygen cannot enter and destroy the cells via oxidative degradation.

Thin-film methods for making the solar panels may use a minimal amount of active material. This may be accomplished by sandwiching the active material between two panes of transparent materials. Any appropriate material may be used as the active material for making the thin solar panels. These materials may include, but are limited to cadmium telluride, copper indium gallium selenide, amorphous silicon, graphene, diamond, another type of material, silicon, or combinations thereof.

The panel may be coated with a hydrophobic material that prevents at least some water based substances from adhering to the panel. In some examples, the hydrophobic material includes, but is not limited to, oils, alkanes, other types of materials, or combinations thereof.

The wireless communication tower may include at least one reflector attached to its exterior that directs light towards the solar panel. The reflector may be positioned above the panels and above regions of the wireless communication tower where shadows are typically cast.

The solar panel may include a processor that causes the wireless communication device to send a message relating to power generation involving the solar panel.

The message may include an amount of power generated with the solar panel, an amount of power stored in the battery, an amount of power used by the wireless communication tower, another type of message, or combinations thereof.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples described herein, but is to be accorded the broadest scope consistent with the principles and novel features disclosed herein.

What is claimed is:

1. A solar panel, comprising:
a photovoltaic cell that includes a characteristic of being thin enough to bend without imposing strain that damages the photovoltaic cell;
wherein the photovoltaic cell is configured to wrap around a wireless communication tower.

2. The solar panel of claim 1, wherein the solar panel directs power to a battery attached to the wireless communication tower.

3. The solar panel of claim 2, wherein the battery is located in a position of the wireless communication tower where a power meter would otherwise generally occupy.

4. The solar panel of claim 1, wherein the solar panel is laminated.

5. The solar panel of claim 1, wherein the solar panel charges at least one battery connected to a wireless tower during sunlight time periods and wireless communication devices draw electricity from the at least one battery connected to the wireless tower during sunlight hours and during time periods where the solar panel is without exposure to the sunlight.

6. The solar panel of claim 1, wherein a single photovoltaic cell of the solar panel wraps around an entire circumference of the wireless communication tower.

7. The solar panel of claim 1, wherein the solar panel occupies at least a fifth of a length of the wireless communication tower's height.

8. The solar panel of claim 1, wherein the battery is located at a base section of the wireless communication tower.

9. The solar panel of claim 1, wherein the solar panel is located at a base section of the wireless communication tower.

10. The solar panel of claim 1, wherein the solar panel is coated with a hydrophobic material that prevents at least some water based substances from adhering to the solar panel.

11. The solar panel of claim 1, wherein the solar panel includes a self-cleaning mechanism.

12. The solar panel of claim 1, wherein the wireless communication tower includes at least one reflector attached to an exterior portion of the wireless communication tower, the at least one reflector being configured to directs light towards the solar panel.

13. The solar panel of claim 12, wherein the at least one reflector is positioned above the solar panel above a region of the wireless communication tower where shadows are cast.

14. The solar panel of claim 1, wherein the solar panel receives light regardless of a position of a sun during daylight periods of a day.

15. The solar panel of claim 1, wherein a battery is in communication with at least one wireless communication device incorporated into the wireless communication tower.

16. The solar panel of claim 15, wherein a processor causes the at least one wireless communication device to send a message relating to power generation involving the solar panel.

17. The solar panel of claim 16, wherein the message includes an amount of power generated with the solar panel; and
wherein the message is sent to a wireless communication device.

18. The solar panel of claim 16, wherein the message includes an amount of power stored in the battery.

19. The solar panel of claim 16, wherein the message includes an amount of power used by the wireless communication tower.

20. A solar panel, comprising:
a photovoltaic cell configured to wrap around a wireless communication tower.

21. A wireless communication tower, comprising:
a solar panel attached to its outside surface;
wherein the solar panel is wrapped around an outer surface of the wireless communication tower.
